(19) United States
(12) Patent Application Publication
(10) Pub. No.: US 2006/0006767 A1
(43) Pub. Date: Jan. 12, 2006

(54) Steering column assembly

(75) Inventors: Jochem Fischer, Ostfildern (DE); Sven Druhmann, Bielefeld (DE)

Correspondence Address: HENRY M FEIEREISEN, LLC, 350 FIFTH AVENUE, SUITE 4714, NEW YORK, NY, 10118, US

(73) Assignee: BENTELER AUTOMOBILTECHNIK GMBH, Paderborn (DE)

(21) Appl. No.: 11/174,014

(22) Filed: Jul. 1, 2005

(30) Foreign Application Priority Data
Jul. 8, 2004 (DE) 10 2004 033 230.4

(51) Int. Cl. H01L 41/08

(52) U.S. Cl. 310/338

(57) ABSTRACT

A steering column assembly for a motor vehicle includes a steering column having a steering-column portion constructed as hollow profile, and an active system for vibration damping. The active system includes plural piezoelectric elements which are disposed in offset relationship about a reference circle inside on the steering-column portion and constructed for clocked operation as sensor to detect the presence of interfering vibrations, when operating in sensor mode, and as actuator to introduce into the system a mechanical force as counter vibration or compensation vibration, when operating in actuator mode.

### CROSS-REFERENCES TO RELATED APPLICATIONS

This application claims the priority of German Patent Application, Serial No. 10 2004 033 230.4, filed Jul. 8, 2004, pursuant to 35 U.S.C. 119(a)-(d), the subject matter of which is incorporated herein by reference.

### BACKGROUND OF THE INVENTION

The present invention relates, in general, to a steering column assembly for a motor vehicle.

Nothing in the following discussion of the state of the art is to be construed as an admission of prior art.

German patent publication DE 102 26 477 A1 discloses a steering column which has attached to its outside piezoelectric actuators. In addition, there is provided a separate sensor for detecting vibrations. The actuator and the sensor communicate with a control unit. The sensor generates signals which are commensurate with the presence of interfering vibrations and transmitted to the control unit for generating control signals for the actuators which are then introduced into the system as a counter vibration in opposition to the interfering vibration.

It would be desirable and advantageous to provide an improved steering column assembly to obviate prior art shortcomings and to improve the damping function of interfering vibrations.

### SUMMARY OF THE INVENTION

According to one aspect of the present invention, a steering column assembly for a motor vehicle includes a steering column having a steering-column portion constructed as hollow profile, and an active system for vibration damping, wherein the active system includes plural piezoelectric elements disposed interiorly on the steering-column portion in offset relationship about a reference circle and constructed for operating as sensor and operating as actuator.

The present invention resolves prior art problems by incorporating piezoelectric elements which operate as sensor as well as actuator. An example of such a sensor/actuator element includes a piezoelectric element on the basis of piezoceramic fiber composite materials. The used piezoelectric elements have a multifunctional fiber composite structure and are able to convert one physical variable to another physical variable.

The steering column is configured to have at least one steering-column portion constructed as hollow profile, with one or more of the piezoelectric elements disposed inside the steering-column portion. As a result, the piezoelectric elements are protected from external impacts. Moreover, the piezoelectric elements are arranged inside the steering-column portion in proximity of the neutral fiber of the steering column so as to operate especially effective. Several piezoelectric elements are arranged about a reference circle on the steering-column portion so as to realize a superior vibration damping effect.

According to another feature of the present invention, the steering column is held by a steering-column support, with the piezoelectric elements arranged in an area of the steering-column support.

The piezoelectric elements are used as sensor for detecting the presence of oscillations or vibrations on the steering column during operation of the motor vehicle. Each piezoelectric element is hereby sequentially clocked to operate as sensor to ascertain changes in length and as actuator in a next clocking to dampen vibration. Vibration damping is realized through deformation of the piezoelectric element, especially through change in length. As a consequence, mechanical forces are introduced into the system to generate a counter vibration or compensation vibration that opposes the presence of an interfering vibration. The clock frequency is predefined by a control and regulating unit of the system.

According to another feature of the present invention, the piezoelectric elements can be so constructed that, on one hand, they are forced to change in length, when a voltage is applied, and that in the reverse case, a voltage can be detected on the piezoelectric elements via the change in length to provide information about the length change and thus the interfering vibration.

In this way, the active system for vibration damping on a steering column is realized which can be constructed in the absence of a separate sensor while being reliable and very sensitive in operation. Especially the absence of a separate sensor results in an appreciable improvement of the system. As sensor and actuator are present at the same location, detrimental influences and inaccuracies in measurement, as experienced heretofore as a consequence of the geometric distance of components, can now be eliminated.

According to another feature of the present invention, the piezoelectric elements can be arranged on the steering-column support in an area of attachment of the steering column to the instrument panel of the motor vehicle. In this way, operation of the piezoelectric elements is especially effective.

### BRIEF DESCRIPTION OF THE DRAWING

Other features and advantages of the present invention will be more readily apparent upon reading the following description of currently preferred exemplified embodiments of the invention with reference to the accompanying drawing, in which:

FIG. 1 is a simplified schematic sectional view of a steering column assembly according to the present invention;

FIG. 2 is a longitudinal section of a detail of the steering column assembly;

FIG. 3 is a sectional view of the steering column assembly, taken along the line III-III in FIG. 2; and

FIG. 4 shows graphical illustrations of two clock waveforms to illustrate the clocking operation of a piezoelectric element in accordance of the present invention in sensor mode and actuator mode.

### DETAILED DESCRIPTION OF PREFERRED EMBODIMENTS

Throughout all the Figures, same or corresponding elements are generally indicated by same reference numerals. These depicted embodiments are to be understood as illustrative of the invention and not as limiting in any way. It should also be understood that the drawings are not necessarily to scale and that the embodiments are sometimes illustrated by graphic symbols, phantom lines, diagrammatic representations and fragmentary views. In certain instances, details which are not necessary for an understanding of the present invention or which render other details difficult to perceive may have been omitted.

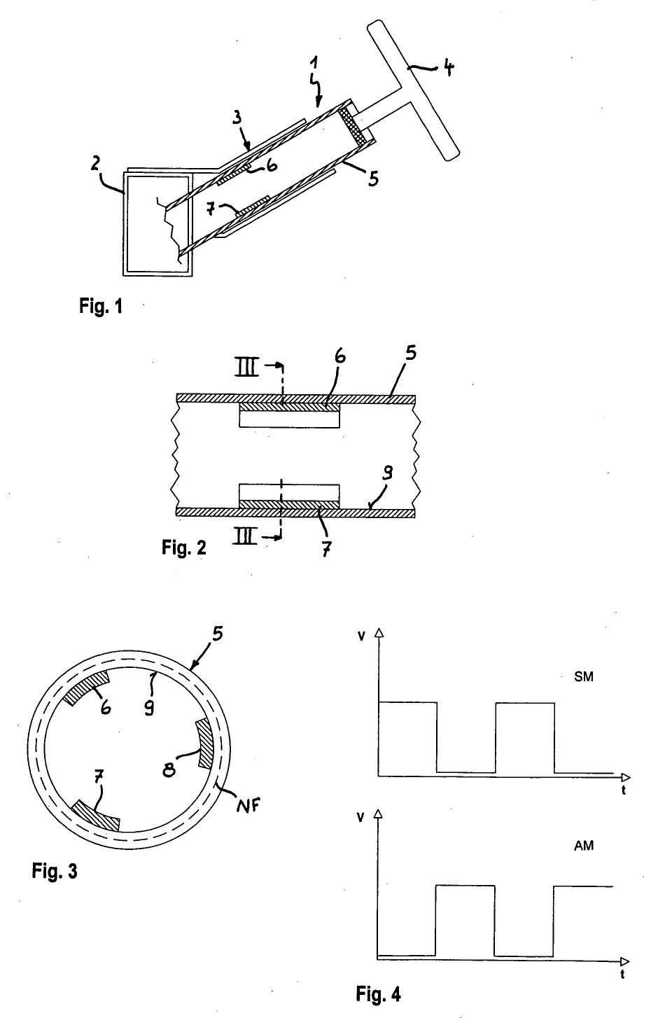

Turning now to the drawing, and in particular to FIG. 1, there is shown a simplified schematic sectional view of a steering column assembly according to the present invention, including a steering column, generally designated by reference numeral 1, for a motor vehicle. The steering column 1 is connected to an instrument panel 2 via a steering-column support 3. The steering column 1 is configured in such a way as to have at least one steering-column portion 5 which is constructed in the form of a hollow profile. Of course, the steering column 1 may be constructed entirely in the form of a hollow profile, and may also be configured in one part or composed of several parts. Reference numeral 4 designates a steering wheel connected to the steering column 1.

Attached to the steering-column portion 5 inside the steering column 1 in the area of the steering-column support 3 are piezoelectric elements 6, 7, 8. As shown in particular in FIGS. 2 and 3, the piezoelectric elements 6, 7, 8 are arranged in offset relationship about a reference circle at the inside wall surface 9 of the steering-column portion 5. The piezoelectric elements 6, 7, 8 are hereby located in close proximity to the neutral fiber NF of the steering-column portion 5 and are thus able to realize maximum efficiency. The piezoelectric elements 6, 7, 8 are clock-controlled by an unillustrated control and regulating unit so as to operate alternatingly, depending on the clocking, as sensor (sensor mode SM) and as actuator (actuator mode AM).

Clocking in sensor mode SM and in actuator mode AM of the piezoelectric elements 6, 7, 8 is shown in particular in FIG. 4, depicting two graphs of clock waveforms by way of relationship between the voltage as a function of time. The sensor mode SM of the piezoelectric elements 6, 7, 8 is hereby shown in the upper graph of FIG. 4, whereas the actuator mode AM of the piezoelectric elements 6, 7, 8 is shown in the lower graph of FIG. 4. As can be seen from FIG. 4, the piezoelectric elements 6, 7, 8 operate alternatingly in sensor mode SM and in actuator mode AM. When a vibration or oscillation is introduced, the piezoelectric elements 6, 7, 8 undergo deformations, in particular a change in length, resulting in a measurable voltage or change in voltage. This is ascertained and evaluated by the control and regulating unit. Depending on the evaluation, the control and regulating unit activates the piezoelectric elements, 6, 7, 8 to operate in actuator mode AM, thereby forcing a direction-controlled change in length. As a consequence of this mechanical force introduction, a counter vibration or compensating vibrations is generated in the system to allow suppression or damping of an interfering vibration.

While the invention has been illustrated and described in connection with currently preferred embodiments shown and described in detail, it is not intended to be limited to the details shown since various modifications and structural changes may be made without departing in any way from the spirit of the present invention. The embodiments were chosen and described in order to best explain the principles of the invention and practical application to thereby enable a person skilled in the art to best utilize the invention and various embodiments with various modifications as are suited to the particular use contemplated.

What is claimed as new and desired to be protected by Letters Patent is set forth in the appended claims and includes equivalents of the elements recited therein:

1. A steering column assembly for a motor vehicle, comprising:
a steering column having a steering-column portion constructed as hollow profile; and
an active system for vibration damping, said active system including plural piezoelectric elements disposed interiorly on the steering-column portion in offset relationship about a reference circle and constructed for operating as sensor and operating as actuator.

2. The steering column assembly of claim 1, and further comprising a steering-column support for holding the steering column, said piezoelectric elements being arranged in an area of the steering-column support.

3. The steering column assembly of claim 1, wherein the piezoelectric elements are constructed on the basis of a piezoceramic fiber composite.

4. The steering column assembly of claim 1, wherein the piezoelectric elements are constructed for alternating operation in sensor mode to ascertain a change in length and in actuator mode during a next clocking to dampen vibration.

5. The steering column assembly of claim 4, and further comprising a control and regulating unit operatively connected to the piezoelectric elements for providing a predefined clock frequency for clocking of the piezoelectric elements.

6. The steering column assembly of claim 1, wherein the piezoelectric elements are constructed to undergo a change in length, when a voltage is applied, and to allow detection of a voltage on the piezoelectric elements, when the length has changed so as to provide information about the change in length and thus an interfering vibration.

7. The steering column assembly of claim 2, wherein the piezoelectric elements are arranged on the steering-column support in an area of attachment of the steering column to an instrument panel of the motor vehicle.
